(19) United States
(12) Patent Application Publication
(10) Pub. No.: US 2016/0254398 A1
(43) Pub. Date: Sep. 1, 2016

(54) AN APPARATUS AND A METHOD FOR DETECTING PHOTONS

(71) Applicant: NOKIA TECHOLOGIES OY, Espoo (FI)

(72) Inventors: Tim ECHTERMEYER, Manchester (GB); Elefterios LIDORIKIS, Ioannina (GR); Alan COLLI, Cambridge (GB); Jani KIVIOJA, Cambourne (GB); Andrea FERRARI, Espoo (FI)

(21) Appl. No.: 15/032,372

(22) PCT Filed: Jan. 29, 2014
(86) PCT No.: PCT/FI2014/050071

§ 371 Date: Apr. 27, 2016

(30) Foreign Application Priority Data
Nov. 5, 2013 (GR) 20130100631

(51) Int. Cl. H01L 31/0232; H01L 31/0224

(52) U.S. Cl. CPC H01L 31/02327; H01L 31/0224

(57) ABSTRACT

An apparatus (100) comprising: semiconductor (2); and an asymmetric electrode arrangement (10) comprising a first electrode (11), a second electrode (12) separated from the first electrode across a portion of the semiconductor and at least one surface plasmon polariton generator (20) associated with at least the first electrode (11).

### TECHNOLOGICAL FIELD

Embodiments of the present invention relate to an apparatus and a method. In particular, they relate to an apparatus configured to detect incident photons.

### BACKGROUND

A photo-detector is an apparatus that has a measurable electrical characteristic that changes with incidence of photons. For example, a photo-detector may transduce a photon flux into an electrical current or voltage. Photo-detectors may use semiconductors. When an incident photon is absorbed, one or more electrons are raised to a higher energy level where they produce a photocurrent.

### BRIEF SUMMARY

According to various, but not necessarily all, embodiments of the invention there is provided an apparatus comprising: semiconductor; and an asymmetric electrode arrangement comprising a first electrode, a second electrode separated from the first electrode across a portion of the semiconductor and at least one surface plasmon polariton generator associated with at least the first electrode.

According to various, but not necessarily all, embodiments of the invention there is provided a method comprising: providing an asymmetric electrode arrangement comprising a first electrode, and a second electrode separated from the first electrode across a portion of the semiconductor, providing an optical coupler at at least a first area of the first electrode; providing a conductive path along a surface of the first electrode from the first area of the first electrode to a second area of the first electrode that contacts the semiconductor.

According to various, but not necessarily all, embodiments of the invention there is provided an apparatus comprising: graphene; and an asymmetric electrode arrangement comprising a first electrode, a second electrode separated from the first electrode across a portion of the graphene and at least one surface plasmon polariton generator associated with at least the first electrode.

According to various, but not necessarily all, embodiments of the invention there is provided an apparatus comprising: a material with a Fermi level and a low density of states near the Fermi level; and an asymmetric electrode arrangement comprising a first electrode, a second electrode separated from the first electrode across a portion of the graphene and at least one surface plasmon polariton generator associated with at least the first electrode.

### BRIEF DESCRIPTION

For a better understanding of various examples that are useful for understanding the brief description, reference will now be made by way of example only to the accompanying drawings in which:

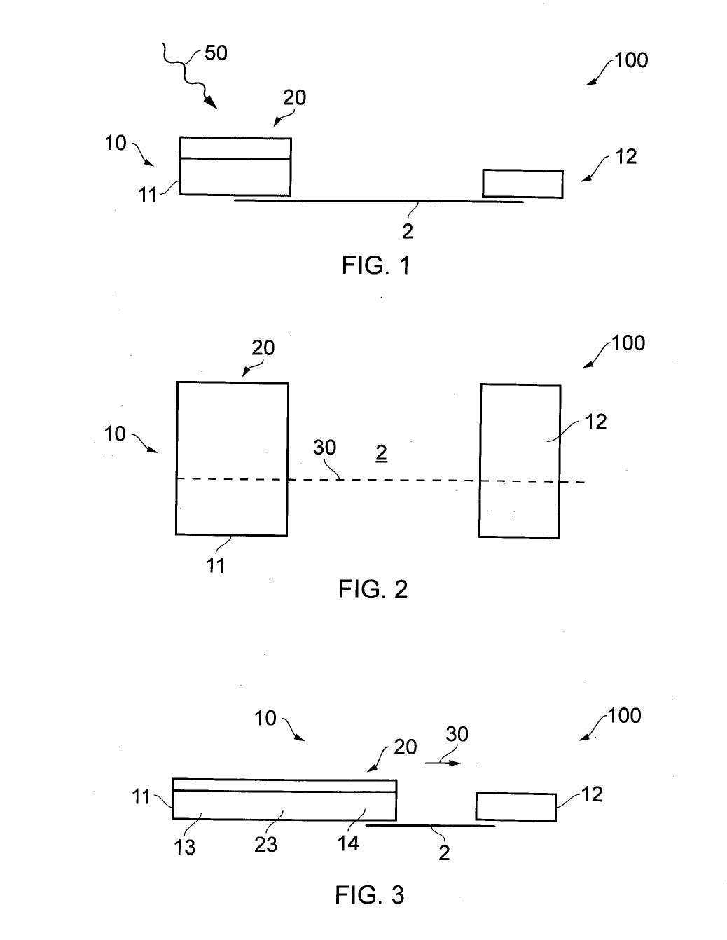

FIG. 1 illustrates an example of the apparatus;

FIG. 2 illustrates another example of the apparatus;

FIG. 3 illustrates another example of the apparatus;

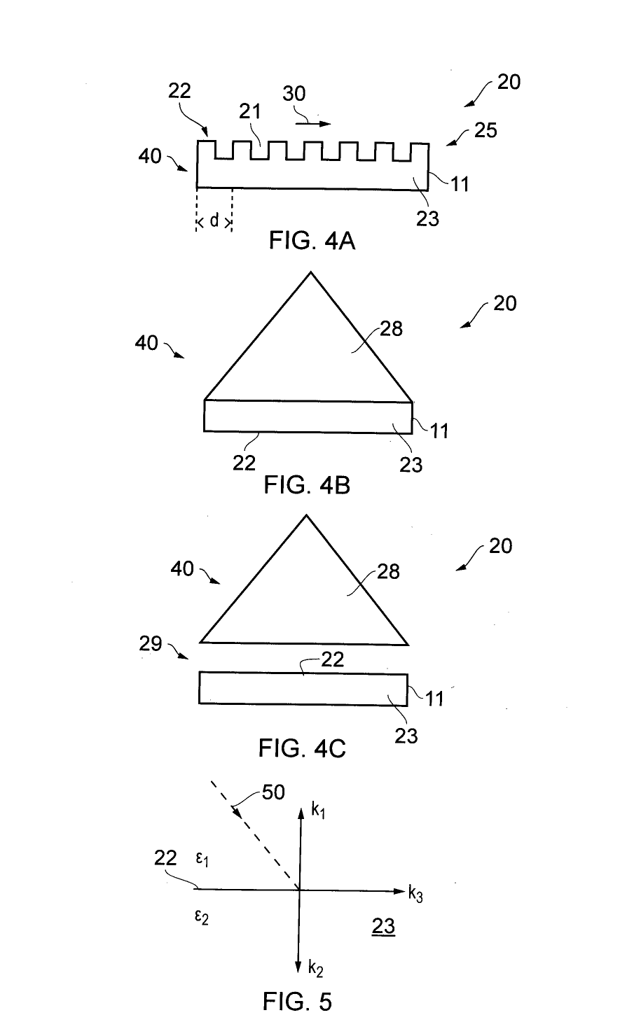

FIGS. 4A to 4C illustrate examples of plasmon polariton generators;

FIG. 5 illustrates wave vector matching of an incident photon and a surface plasmon;

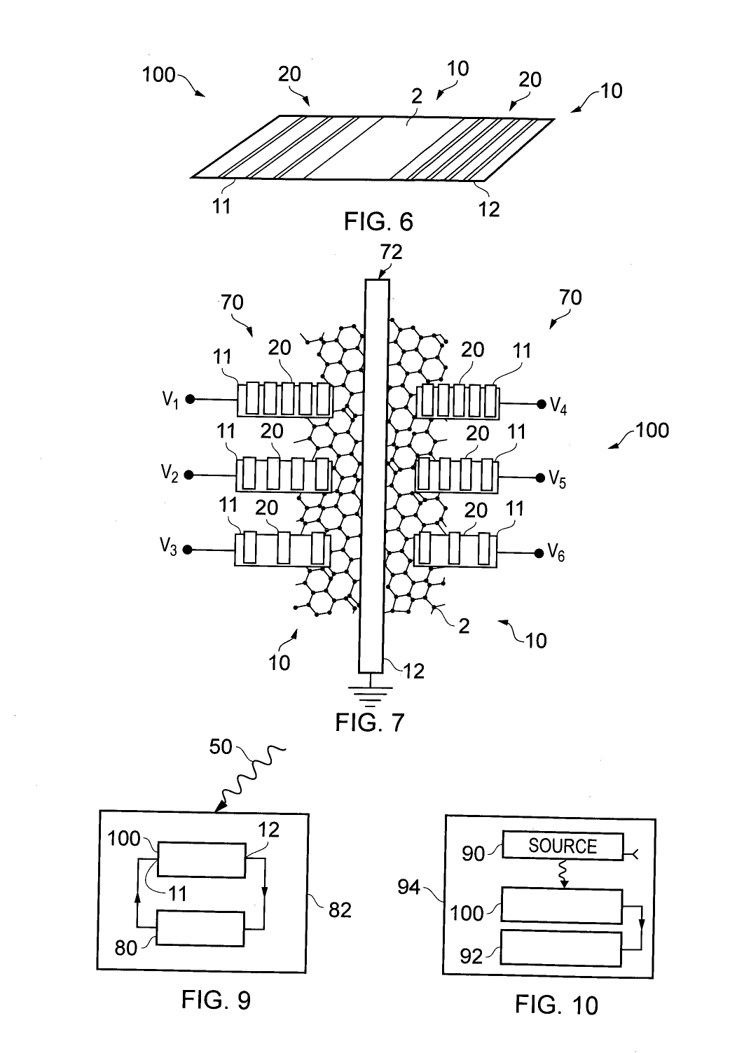

FIG. 6 illustrates another example of the apparatus;

FIG. 7 illustrates another example of the apparatus;

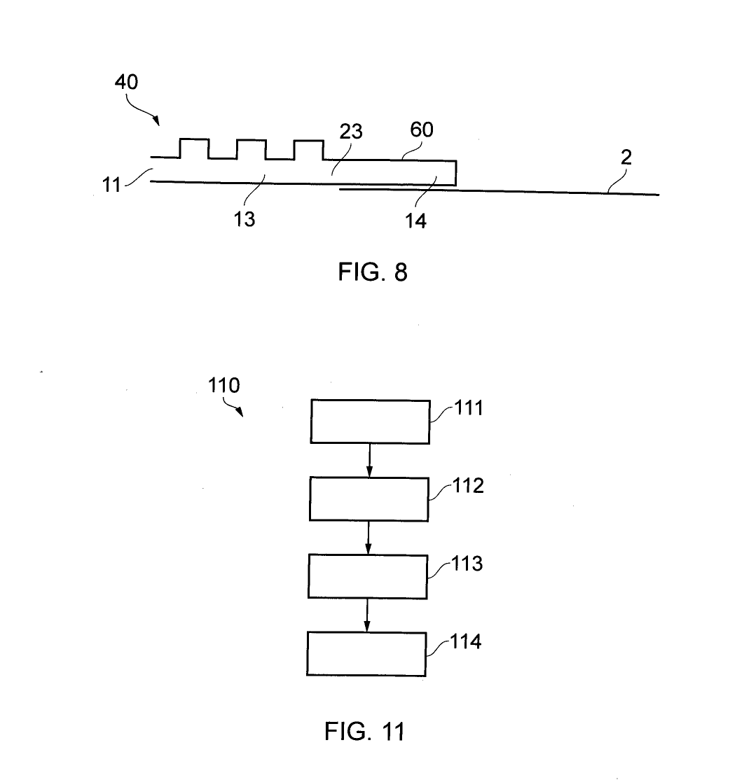

FIG. 8 illustrates an example of an asymmetric first electrode;

FIG. 9 illustrates a narrowband photo detector comprising the apparatus;

FIG. 10 illustrates an analyte sensor comprising the apparatus; and

FIG. 11 illustrates a method.

### DETAILED DESCRIPTION

The Figures illustrate an apparatus 100 comprising semiconductor 2 and an asymmetric electrode arrangement 10 comprising a first electrode 11, a second electrode 12 separated from the first electrode across a portion of the semiconductor 2 and at least one surface plasmon polariton generator 20 associated with the first electrode 11.

In the following description various examples of the apparatus 100 are described, where the semiconductor 2 is graphene. However, the semiconductor 2 may, in other examples, be a different semiconductor.

The semiconductor 2 may, for example, be a two-dimensional (2) semiconductor such as graphene or molybdenum disulphide (MoS₂)

Alternatively, the semiconductor 2 may, for example, be bulk semiconductor or a thin-film semiconductor. Examples include silicon (Si), gallium arsenide (GaAs) and zinc oxide (ZnO).

In some but not necessarily all examples, the semiconductor 2 may have a low photon absorption. In some but not necessarily all examples, the semiconductor 2 may have a high electron mobility. Thus In some but not necessarily all examples, the semiconductor 2 may have an electron mobility greater than 5 k cm²V⁻¹s⁻¹ and a photon absorption of less than 5% or 10%.

FIG. 1 illustrates an example of an apparatus 100 in cross-section. The apparatus 100, in this example, is an optoelectronic apparatus that has electrical characteristics that vary in the presence of photons 50.

The apparatus 100 comprises graphene 2 and an asymmetric electrode arrangement 10 comprising a first electrode 11, a second electrode 12 separated from the first electrode across a portion of the graphene 2 and at least one surface plasmon polariton generator 20 associated with the first electrode 11.

The surface plasmon polariton generator 20 couples incident photons 50 to surface plasmons associated with the first electrode 11. The photon-surface plasmon interaction propagates as a surface plasmon polariton to the graphene 2 where decoupling of the polariton and interaction of the photon and graphene occurs.

The asymmetric electrode arrangement 10 results in a net change in the electrical characteristics of the graphene 2, which may be detected via the first electrode 11 and the second electrode 12.

FIG. 2 illustrates an example of an apparatus 100 in plan view from above. The apparatus 100 may be similar to the apparatus 100 described previously with reference to FIG. 1 and similar references are used to denote similar features. The description of those features in relation to FIG. 1 is also applicable to the features in FIG. 2.

In FIG. 2, a virtual line 30 is illustrated that extends through the first electrode 11, the portion of graphene 2 between the first electrode 11 and the second electrode 12 and the second electrode 12.

The surface plasmon polariton generator 20 is configured to generate surface plasmon polaritons and to transport the generated surface plasmon polaritons to the graphene 2.

In order to transport the generated surface plasmon polaritons to the graphene 2, the surface plasmon polariton generator is configured to provide a continuous plasma over at least several micrometers in a direction along the virtual line 30 through the first electrode 11, the graphene 2 and the second electrode 12. Continuous conductive material such as metal may be used to provide a continuous plasma.

FIG. 3 illustrates an example of an apparatus 100 in side view. The apparatus 100 may be similar to the apparatus 100 described previously with reference to FIGS. 1 and/or FIG. 2.

Similar references are used to denote similar features. The description of those features in relation to FIG. 1 and FIG. 2 is also applicable to the features in FIG. 3.

In FIG. 3, the plasmon polariton generator 20 is configured to generate surface plasmon polaritons and to transport the generated surface plasmon polaritons from a first area 13 to a second area 14.

The first area 13 is part of the first electrode 11. It does not overlie exposed graphene 2.

In some but not necessarily all examples, the first area 13 is not in physical or direct electrical contact with the graphene 2. It does not overlie the graphene 2.

The second area 14 is part of the first electrode 11. The second area 14 is in direct electrical contact with the graphene 2 and may be in physical contact. It overlies the graphene 2.

In this example, the plasmon polariton generator 20 may be configured to generate a continuous plasma form the first area 13 to the second area 14 in a direction parallel to the line 30 through the first electrode 11, the graphene 2 and the second electrode 12. The distance between the first area 13 and the second area 14 may, in some examples, be over several micrometers. Continuous conductive material 23 such as metal may be used to provide a continuous plasma.

FIGS. 4A to 4C illustrate examples of plasmon polariton generators 20. In these examples, the plasmon polariton generators 20 comprise optical couplers 40 in combination with continuous conductive material 23. The continuous conductive material 23 is part of the first electrode 11.

A conductive path is provided along a continuous surface 22 of the first electrode 11. The conductive path may extend, as illustrated in FIG. 3, from the first area 13 to the second area 14.

As illustrated in FIG. 8, the optical coupler 40 may be associated with the first area 13 but not with the second area 14.

In the example of FIG. 4A, the optical coupler 40 comprises a surface structure 25 that has periodicity in a direction parallel to the line 30.

The surface structure 25 has a repeat pattern of period d nm. The surface structure 25, in this example, is a nanoscale structure and d<1 μm. The surface structure 25 is continuous on a scale significantly larger than its period d and it may extend for at least several μm.

The surface structure 25 may be formed by a periodic pattern, for example, undulations or channels 21, in an upper surface 22 of the conductive material 23 of the first electrode 11.

In the illustrated example, the upper surface 22 of the conductive material 23 of the first electrode 11 has periodic profile modulations 21.

The periodicity of the surface structure 25 is at least in a direction parallel to the line 30 through the first electrode 11, the graphene 2 and the second electrode 12.

In the illustrated example, the surface structure 25 is a grating. It comprises alternate high and low profile portions. In this example, the grating 25 is a regular grating and all the high portions are of the same size and all of the low portions are of the same size. The high portions and low portions may be of the same size.

The boundaries of the high and low profile portions are parallel to each other and extend orthogonally to the line 30. The repetition of the periodic surface structure 25, the periodicity, is in this example parallel to the line 30.

In the examples of FIG. 4B and 4C, the optical coupler 40 comprises a prism 28. In FIG. 4B, the prism 28 contacts the conductive material 23 of the first electrode 11. In FIG. 4C, the prism 28 is separated from the conductive material 23 of the first electrode 11 by a very small gap 29.

As illustrated in FIG. 5, a surface plasmon polariton generator 20 couples incident photons 50 with surface plasmons. This is achieved by matching the wave vector of the incident photon 50 to the wave vector of the surface plasmon.

In the simple example of FIG. 5 a wave vector is represented as two components (a, b), where a is the component parallel to an interface defined by the surface 22 of the conductive material 23 and b is the component orthogonal to that interface.

If we assume that the conductive material 23 has a dielectric constant ε₂, and that the dielectric material (e.g. air) adjacent to the interface has dielectric constant ε₁, then the boundary conditions for coupling of the surface plasmon polariton and the incident photon are:

k₁/ε₁+k₂/e₂=0

k₃²+k₁²=ε₁(ω/c)²

k₃²+k₂²=ε₂(ω/c)²

where the incident photon has wave vector (k₃, −k₁), the surface plasmon polariton has wave vector (k₃, k₂), ω is the frequency of the incident photon and c is the speed of light.

The surface plasmon polariton generator 20 is configured to enable wave vector matching between the incident photon 50 and the surface plasmon. The surface plasmon polariton generator 20 is configured to impart a component of momentum (wave vector) to an incident photon 50 in at least a direction parallel to the line 30 through the first electrode 11, the graphene 2 and the second electrode 12 (i.e. parallel to the interface).

Referring back to the example illustrated in FIG. 3. In this example, asymmetry between the first electrode 11 and the second electrode 12 is achieved by associating a surface plasmon polariton generator 20 with the first electrode but not associating a surface plasmon polariton generator 20 with the second electrode 12.

However, asymmetry in the asymmetrical electrode arrangement 10 may be achieved in other ways.

For example, as illustrated in FIG. 6, the first electrode 11 may be associated with a first surface plasmon polariton generator 20 and the second electrode 12 may be associated with a second different surface plasmon polariton generator 20.

For example, the first surface plasmon polariton generator 20 may be configured to selectively couple photons of a first frequency and the second surface plasmon polariton generator 20 may be configured to selectively couple photons of a second frequency. In the illustrated example, this is achieved by using gratings 25 of different periods for the first surface plasmon polariton generator 20 and the second surface plasmon polariton generator 20.

FIG. 7 illustrates an example of an apparatus 100 where the asymmetric electrode arrangement 10 comprises a plurality 70 of first electrodes 11, each of which is associated with a different surface plasmon polariton generator 20. The different surface plasmon polariton generators 20 may be configured to selectively couple photons of different particular frequencies. In the illustrated example, this is achieved by using gratings 25 of different periods for each of the first surface plasmon polariton generators 20.

In the example of FIG. 7 , the second electrode 12 is a common electrode 72 separated from the plurality of first electrodes 11 by the graphene 2.

FIG. 8 illustrates an example of an asymmetric first electrode 11. The first electrode comprises a first portion 13 and a second portion 14. The first portion 13 provides the optical coupler 40 in the form of a periodic grating 25 which operates as the surface plasmon polariton generator 20 as described with reference to FIG. 4A. The second portion 14 does not provide a periodic grating 25. It is flat. It operates to transport generated surface plasmon polaritons to the graphene 2. In this example, the second portion 14 is adjacent to the graphene 2 and the first portion 13 is not.

The upper surface 60 of the second portion 14 may, in some examples, operate as a substrate for the adsorption of analyte.

FIG. 9 illustrates a narrowband photo detector 82. The apparatus 100 is used to detect a photon 50 of a particular frequency or photons 50 of particular frequencies depending upon implementation.

A detector 80 is connected to the or each first electrode 11 and the second electrode 12 of the apparatus 100 and detects changes in the electrical characteristics of the graphene 2. For example, the graphene may produce a photo-current dependent upon the number of incident photons 50 of the correct frequency at the surface plasmon polariton generator 20 associated with the or each first electrode 11. The ‘correct’ frequency is determined by the boundary conditions described with reference to FIG. 5.

FIG. 10 illustrates an analyte sensor 94.

The apparatus 100 detects a photon 50 of a particular frequency or photons of particular frequencies depending upon implementation.

A detector 80 is connected to the or each first electrode 11 and the second electrode 12 of the apparatus 100 and detects changes in the electrical characteristics of the graphene 2. For example, the graphene may produce a photo-current dependent upon the number of incident photons 50 of the correct frequency at the surface plasmon polariton generator 20 associated with the or each first electrode 11. The ‘correct’ frequency is determined by the boundary conditions described with reference to FIG. 5.

The analyte sensor 94 additionally comprises a source 90 of photons 50 at the correct frequency. The source 90 may be a narrowband source such as a laser or a alternatively a light emitting diode.

When an analyte adsorbs to the exposed graphene 2 and/or the first electrode 11 adjacent to the graphene 2, there may be a change in how the electrical characteristics of the graphene 2 change with incident photons. The change in electrical characteristics may be calibrated against type and/or concentration of analyte.

FIG. 11 illustrates a method 110 comprising:

at block 111 providing an asymmetric electrode arrangement 10 comprising a first electrode 11 and a second electrode 12 separated from the first electrode across a portion of the graphene 2,

at block 112 providing an optical coupler 40 at at least a first area 13 of the first electrode 11,

at block 113 providing a conductive path along a surface of the first electrode 11 adjacent to a dielectric from the first area 13 of the first electrode to a second area 14 of the first electrode 11 that contacts the graphene 2;

at block 114 detecting electrical characteristics of the graphene 2 using the first electrode 11 and the second electrode 12.

It will be appreciated from the described examples, that the apparatus 10 may comprise:

graphene 2; and an asymmetric electrode arrangement 10 comprising a first electrode 11, a second electrode 12 separated from the first electrode 11 across a portion of the graphene 2, wherein the first electrode 11 extends from a first area 13 that does not contact the graphene to a second area 14 that does contact the graphene, and wherein the first electrode 11 at the first area 13 is associated with an optical coupler 40. The optical coupler 40 may be configured to couple photons to surface plasmons to generate surface plasmon polaritons that are transported from the first area 13 to the second area 14.

As used here ‘module’ refers to a unit or apparatus that excludes certain parts/components that would be added by an end manufacturer or a user. The apparatus 100 may be a module.

The term ‘comprise’ is used in this document with an inclusive not an exclusive meaning. That is any reference to X comprising Y indicates that X may comprise only one Y or may comprise more than one Y. If it is intended to use ‘comprise’ with an exclusive meaning then it will be made clear in the context by referring to “comprising only one” or by using “consisting”.

In this brief description, reference has been made to various examples. The description of features or functions in relation to an example indicates that those features or functions are present in that example. The use of the term ‘example’ or ‘for example’ or ‘may’ in the text denotes, whether explicitly stated or not, that such features or functions are present in at least the described example, whether described as an example or not, and that they can be, but are not necessarily, present in some of or all other examples. Thus ‘example’, ‘for example’ or ‘may’ refers to a particular instance in a class of examples. A property of the instance can be a property of only that instance or a property of the class or a property of a sub-class of the class that includes some but not all of the instances in the class.

Although embodiments of the present invention have been described in the preceding paragraphs with reference to various examples, it should be appreciated that modifications to the examples given can be made without departing from the scope of the invention as claimed.

Semiconductor in this document includes bandgap semiconductors, which have a bandgap, and non-band gap semiconductors, which do not have a bandgap. Non-bandgap semiconductors include semimetals. In some but not necessarily all of the preceding examples, the semiconductor may be a bandgap semiconductor. In some but not necessarily all of the preceding examples, the semiconductor may be a non-bandgap semiconductor.

The semiconductor material is a material with a low density of electron states near the Fermi level, so that the amount of free carriers is too low to screen the collection field generated by the junction at the plasmon polariton generator.

Features described in the preceding description may be used in combinations other than the combinations explicitly described.

Although functions have been described with reference to certain features, those functions may be performable by other features whether described or not.

Although features have been described with reference to certain embodiments, those features may also be present in other embodiments whether described or not.

Whilst endeavoring in the foregoing specification to draw attention to those features of the invention believed to be of particular importance it should be understood that the Applicant claims protection in respect of any patentable feature or combination of features hereinbefore referred to and/or shown in the drawings whether or not particular emphasis has been placed thereon.

1-30. (canceled)

31. An apparatus comprising:
semiconductor; and
an asymmetric electrode arrangement comprising a first electrode, a second electrode separated from the first electrode across a portion of the semiconductor and at least one surface plasmon polariton generator associated with at least the first electrode.

32. An apparatus as claimed in claim 31, wherein the surface plasmon polariton generator is configured to impart a component of momentum to an incident photon in at least a direction parallel to a line through the first electrode, the semiconductor portion and the second electrode.

33. An apparatus as claimed in claim 32, wherein the surface plasmon polariton generator is configured to impart a component of momentum to an incident photon preferentially in the direction parallel to the line through the first electrode, the semiconductor portion and the second electrode.

34. An apparatus as claimed in claim 31, wherein the surface plasmon polariton generator is configured to generate surface plasmon polaritons and to transport the generated surface plasmon polaritons to the semiconductor.

35. An apparatus as claimed in claim 31, wherein the surface plasmon polariton generator is configured to provide a continuous plasma from an area that is not contacting the semiconductor to an area that is contacting the semiconductor.

36. An apparatus as claimed in claim 31, wherein the surface plasmon polariton generator is configured to provide continuous metal from an area that does not contact the semiconductor to an area that does contact the semiconductor.

37. An apparatus as claimed in claim 31, wherein the surface plasmon polariton generator comprises a periodic structure having a periodicity, wherein the periodicity is at least in a direction parallel to a line through the first electrode, the semiconductor portion and the second electrode.

38. An apparatus as claimed in claim 31, wherein the surface plasmon polariton generator comprises a periodic structure having a periodicity, wherein the periodicity is parallel to a line through the first electrode, the semiconductor portion and the second electrode.

39. An apparatus as claimed in claim 31, wherein the periodic structure is a periodic grating.

40. An apparatus as claimed in claim 31, wherein surface plasmon polariton generator comprises conductive material comprising a surface, wherein the surface is continuous and comprises periodic profile modulations.

41. An apparatus as claimed in claim 31, wherein the first electrode is associated with a surface plasmon polariton generator but the second electrode is not associated with a surface plasmon polariton generator.

42. An apparatus as claimed in claim 31, wherein the first electrode is associated with a surface plasmon polariton generator for selectively coupling photons of a first frequency and the second electrode is associated with a surface plasmon polariton generator for selectively coupling photons of a second frequency, different to the first frequency.

43. An apparatus as claimed in claim 31, wherein the asymmetric electrode arrangement comprises a plurality of first electrodes, each of which is associated with a surface plasmon polariton generator for selectively coupling photons of a particular frequency.

44. An apparatus as claimed in claim 43, wherein the second electrode is a common electrode separated from the plurality of first electrodes by the semiconductor.

45. An apparatus as claimed in claim 31, wherein the surface plasmon polariton generator comprises a first portion providing a periodic grating and a second portion that does not provide a periodic grating.

46. An apparatus as claimed in claim 45, wherein the second portion is flat.

47. An apparatus as claimed in claim 45, wherein the second portion is adjacent to the semiconductor portion and the first portion is not.

48. An apparatus as claimed in claim 31, configured as a narrowband photo detector.

49. An apparatus as claimed in claim 31, configured as an analyte sensor wherein at least the semiconductor is exposed for analyte adsorption.

50. An apparatus comprising:
semiconductor; and
an asymmetric electrode arrangement comprising a first electrode, a second electrode separated from the first electrode across a portion of the semiconductor,
wherein the first electrode extends from a first area that does not contact the semiconductor to a second area that does contact the semiconductor, and wherein the first electrode at the first area is associated with an optical coupler.
